(19) United States
(12) Patent Application Publication
(10) Pub. No.: US 2024/0195382 A1
(43) Pub. Date: Jun. 13, 2024

(54) PIEZOELECTRIC PLATE AND MANUFACTURING METHOD THEREFOR, SAW DEVICE AND MANUFACTURING METHOD THEREFOR

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/457,847

(22) Filed: Aug. 29, 2023

(30) Foreign Application Priority Data
Dec. 9, 2022 (CN) 202211584995.1

(51) Int. Cl. H03H 9/02; H03H 3/08; H03H 9/25

(52) U.S. Cl. CPC H03H 9/02897; H03H 3/08; H03H 9/02834; H03H 9/02866; H03H 9/25

(57) ABSTRACT

Disclosed are a piezoelectric plate and a manufacturing method therefor, an SAW device and a manufacturing method therefor. The manufacturing method for the piezoelectric plate provided in the present disclosure includes: sequentially growing a piezoelectric material layer and a protective layer on a first substrate, bonding the protective layer to a second substrate, and then peeling off the first substrate to form a piezoelectric plate including the second substrate, the protective layer and the piezoelectric material layer from bottom to top. A lattice constant of the protective layer is greater than a lattice constant of the piezoelectric material layer. Probability of occurrence of a crack in the piezoelectric material layer may be reduced by the protective layer. Stress generated by lattice mismatch and thermal mismatch is released by transfer of the substrate, so that an occurrence of a crack of the piezoelectric material layer may be avoided.

### CROSS-REFERENCE TO RELATED APPLICATIONS

This application claims priority to Chinese Patent Application No. 202211584995.1, filed on Dec. 9, 2022, which is hereby incorporated by reference in its entirety.

### TECHNICAL FIELD

The present disclosure relates to the field of semiconductor technologies, and in particular, to a piezoelectric plate and a manufacturing method therefor, and an SAW device and a manufacturing method therefor.

### BACKGROUND

At present, surface acoustic wave (SAW) devices are widely applied to social communication systems, of which complexity is getting higher today. Especially, in a time when 5G communication is a current mainstream, SAW devices with high-frequency and low-cost are widely applied to various handheld terminal devices.

A piezoelectric substrate used in an SAW device is usually formed by bonding and thinning a silicon substrate and a single crystal piezoelectric wafer. However, a material of the single crystal piezoelectric wafer is very brittle and easy to crack in a manufacturing process of semiconductor. Therefore, a process menu needs to be designed specifically, resulting in decrease of production efficiency.

### SUMMARY

In view of this, embodiments of the present disclosure provide a piezoelectric plate and a manufacturing method therefor, and an SAW device and a manufacturing method therefor, so as to solve a technical problem that a piezoelectric plate for an SAW device is easy to crack.

According to an aspect of the present disclosure, a manufacturing method for a piezoelectric plate is provided by an embodiment of the present disclosure, including: providing a first substrate; growing a piezoelectric material layer on the first substrate; growing a protective layer on the piezoelectric material layer; bonding the protective layer to a second substrate; and peeling off the first substrate to form a piezoelectric plate including the second substrate, the protective layer and the piezoelectric material layer from bottom to top, where a lattice constant of the protective layer is greater than a lattice constant of the piezoelectric material layer.

In an optional embodiment, the growing a piezoelectric material layer on the first substrate includes: providing a sacrificial layer on the first substrate, and growing the piezoelectric material layer on the sacrificial layer.

In an optional embodiment, a material of the sacrificial layer comprises porous silicon.

In an optional embodiment, the peeling off the first substrate to form a piezoelectric plate including the second substrate, the protective layer and the piezoelectric material layer from bottom to top includes: peeling off the first substrate by directly utilizing thermal stress to realize self-separation of the sacrificial layer.

In an optional embodiment, the bonding the protective layer to a second substrate includes: preparing an acoustic wave reflection layer on the second substrate, and bonding the protective layer to the acoustic wave reflection layer.

In an optional embodiment, a material of the acoustic wave reflection layer is any one of a single-layer porous material, a multi-layer reflecting structure, and a stacked structure of the single-layer porous material and the multi-layer reflecting structure.

In an optional embodiment, a material of the first substrate is one of silicon, sapphire, silicon carbide, and diamond.

In an optional embodiment, the piezoelectric material layer is a single-layer structure of one of AlN, AlGaN, and AlScN, or a multi-layer structure of any combination of AlN, AlGaN, and AlScN.

In an optional embodiment, a surface, away from the second substrate, of the piezoelectric material layer is an N surface.

In an optional embodiment, a material of the protective layer is any one of AlGaN, AlScN, AlInN, and AlInGaN.

According to another aspect of the present disclosure, a manufacturing method for an SAW device is provided by an embodiment of the present disclosure, including: providing a piezoelectric plate as mentioned above; and forming an interdigital transducer on the piezoelectric material layer of the piezoelectric plate.

According to another aspect of the present disclosure, a piezoelectric plate is provided by an embodiment of the present disclosure, including: a second substrate; a protective layer, disposed on the second substrate; and a piezoelectric material layer, disposed on the protective layer, where a lattice constant of the protective layer is greater than a lattice constant of the piezoelectric material layer.

In an optional embodiment, the piezoelectric material layer is a single-layer structure of one of AlN, AlGaN, or AlScN, or a multi-layer structure of any combination of AlN, AlGaN, or AlScN.

In an optional embodiment, a surface, away from the second substrate, of the piezoelectric material layer is an N surface.

In an optional embodiment, a thickness of the piezoelectric material layer is greater than 500 nm.

In an optional embodiment, a material of the protective layer is any one of AlGaN, AlScN, AlInN, and AlInGaN.

In an optional embodiment, the second substrate is one of a silicon substrate, an SOI substrate, and a silicon substrate with silicon dioxide on a surface.

In an optional embodiment, the piezoelectric plate further includes: an acoustic wave reflection layer, disposed between the second substrate and the protective layer.

In an optional embodiment, the acoustic wave reflection layer is a single-layer porous material or a multi-layer reflecting structure.

According to another aspect of the present disclosure, an SAW device is provided by an embodiment of the present disclosure, including: a piezoelectric plate as mentioned above, and an interdigital transducer, where the interdigital transducer is disposed on the piezoelectric material layer of the piezoelectric plate.

### BRIEF DESCRIPTION OF THE DRAWINGS

FIG. 1 is a flowchart of a manufacturing method for a piezoelectric plate according to an embodiment of the present disclosure.

FIG. 2 is a flowchart of a manufacturing method for an SAW device according to an embodiment of the present disclosure.

FIG. 3a to FIG. 3g are schematic structural diagrams corresponding to steps in FIG. 1.

FIG. 4 is a flowchart of a manufacturing method for a piezoelectric plate according to another embodiment of the present disclosure.

FIG. 5a to FIG. 5g are schematic structural diagrams corresponding to steps in FIG. 4.

FIG. 6 is a schematic structural diagram of a piezoelectric plate according to still another embodiment of the present disclosure.

FIG. 7 is a schematic structural diagram of a piezoelectric plate according to yet still another embodiment of the present disclosure.

FIG. 8 is a schematic structural diagram of a piezoelectric plate according to yet still another embodiment of the present disclosure.

### DETAILED DESCRIPTION OF THE EMBODIMENTS

The technical solutions in the embodiments of the present disclosure will be clearly and completely described below with reference to the accompanying drawings in the embodiments of the present disclosure. Apparently, the described embodiments are only a part of the embodiments of the present disclosure, but not all of the embodiments. Based on the embodiments in the present disclosure, all other embodiments obtained by those skilled in the art without creative efforts shall fall within the protection scope of the present disclosure.

In order to solve a technical problem that a piezoelectric plate for an SAW device is easy to crack, the present disclosure provides a piezoelectric plate and a manufacturing method therefor, an SAW device and a manufacturing method therefor. The manufacturing method for the piezoelectric plate provided in the present disclosure includes: sequentially growing a piezoelectric material layer and a protective layer on a first substrate, bonding the protective layer to a second substrate, and then peeling off the first substrate to form a piezoelectric plate including the second substrate, the protective layer and the piezoelectric material layer from bottom to top, where a lattice constant of the protective layer is greater than a lattice constant of the piezoelectric material layer. An arrangement of the protective layer in the present disclosure may reduce probability of occurrence of a crack in the piezoelectric material layer. And a method of transfer of the substrate may further release stress, generated by lattice mismatch and thermal mismatch between the piezoelectric material layer and the first substrate, of the piezoelectric material layer, so that an occurrence of a crack of the piezoelectric material layer may be avoided.

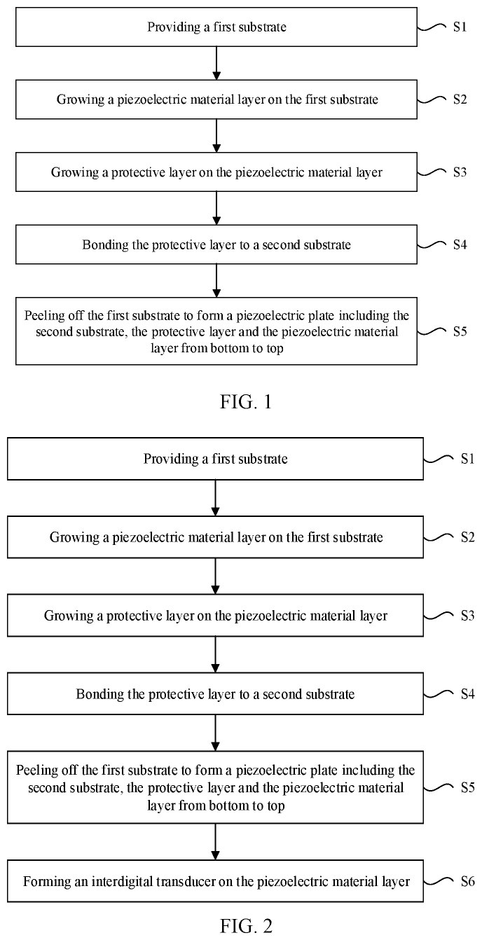

The piezoelectric plate and the manufacturing method therefor and the SAW device and the manufacturing method therefor mentioned in the present disclosure are further illustrated with reference to FIG. 1 to FIG. 8.

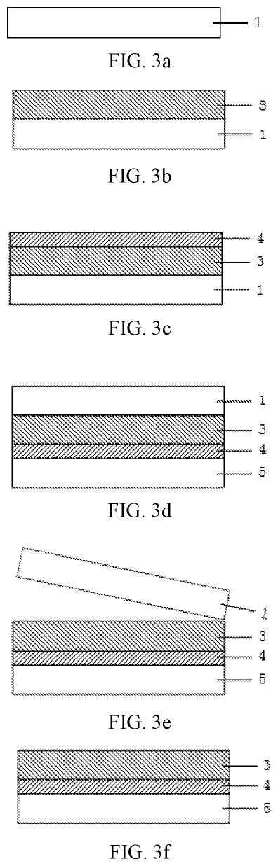

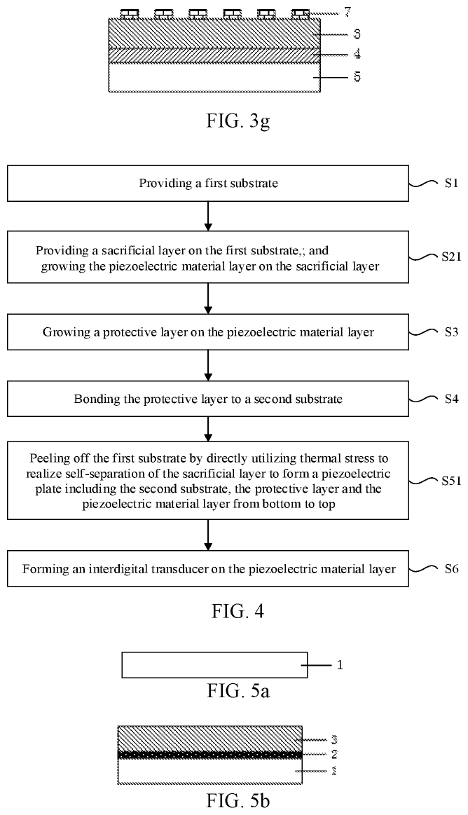

FIG. 1 is a flowchart of a manufacturing method for a piezoelectric plate according to an embodiment of the present disclosure, and FIG. 3a to FIG. 3f are schematic structural diagrams corresponding to steps in FIG. 1.

As shown in FIG. 3a, Step S1: providing a first substrate.

A material of the first substrate 1 is any one of silicon, sapphire, silicon carbide and diamond.

As shown in FIG. 3b, Step S2: growing a piezoelectric material layer on the first substrate.

The piezoelectric material layer 3 is a single-layer structure of one of AlN, AlGaN, and AlScN, or a multi-layer structure of any combination of AlN, AlGaN, and AlScN. A thickness of the piezoelectric material layer 3 is greater than 500 nm.

As shown in FIG. 3c, Step S3: growing a protective layer on the piezoelectric material layer.

A material of the protective layer 4 is any one of AlGaN, AlScN, AlInN, and AlInGaN.

In the present embodiment, growth of the piezoelectric material layer 3 and the protective layer 4 may be obtained by in-situ growth, and may also be obtained by means of Atomic Layer Deposition (ALD), or Chemical Vapor Deposition (CVD), or Molecular Beam Epitaxy (MBE), or Plasma Enhanced Chemical Vapor Deposition (PECVD), or Low Pressure Chemical Vapor Deposition (LPCVD), or Metal-Organic Chemical Vapor Deposition (MOCVD), or a combination thereof.

In the present embodiment, a lattice constant of the protective layer 4 is greater than a lattice constant of the piezoelectric material layer 3. Therefore, an arrangement of the protective layer 4 may introduce a compressive stress to the piezoelectric material layer 3 to balance a tensile stress on the piezoelectric material layer 3 due to lattice mismatch between the piezoelectric material layer 3 and the first substrate 1, so that probability of an occurrence of crack in the piezoelectric material layer 3 is reduced.

As shown in FIG. 3d, Step S4: bonding the protective layer to a second substrate.

The second substrate 5 is any one of a silicon substrate, an SOI substrate, and a silicon substrate with silicon dioxide on a surface.

As shown in FIG. 3e and FIG. 3f, Step S5: peeling off the first substrate to form a piezoelectric plate including the second substrate, the protective layer and the piezoelectric material layer from bottom to top.

In the present embodiment, a method of transfer of the substrate may further release stress, generated by lattice mismatch and thermal mismatch between the piezoelectric material layer 3 and the first substrate lattice 1, of the piezoelectric material layer 3, so that an occurrence of a crack of the piezoelectric material layer may be avoided. A surface, away from the second substrate 5, of the piezoelectric material layer 3 in the piezoelectric plate finally formed is an N surface.

In some embodiments, FIG. 2 is a flowchart of a manufacturing method for an SAW device according to an embodiment of the present disclosure. FIG. 3g is a schematic structural diagram of the SAW device in FIG. 2.

As shown in FIG. 3g, Step S6: forming an interdigital transducer on the piezoelectric material layer.

The SAW device prepared by using the piezoelectric plate described above has good quality, and is not easy to crack, which reduces a production cost and improve production efficiency.

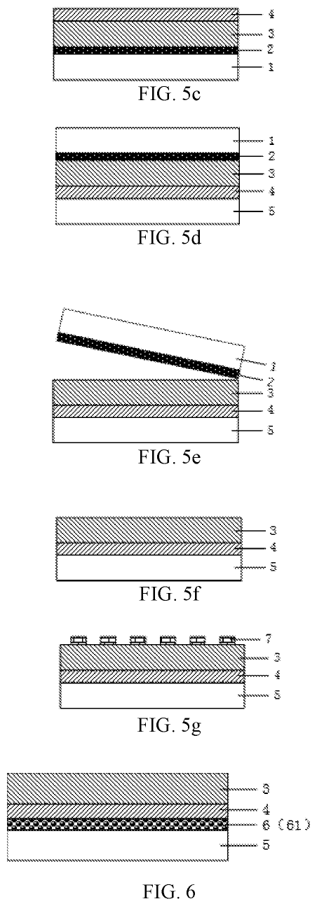

FIG. 4 is a flowchart of a manufacturing method for a piezoelectric plate according to another embodiment of the present disclosure. FIG. 5a to FIG. 5g are schematic structural diagrams corresponding to a process in FIG. 4.

Referring to FIG. 4, FIG. 5a to FIG. 5g and FIG. 1, an embodiment shown in FIG. 4 is approximately the same as content of the embodiment shown in FIG. 1, and a difference merely lies in that Step S2 includes Step S21 and Step S5 includes Step S51.

As shown in FIG. 5a, Step S1: providing a first substrate.

A material of the first substrate 1 is any one of silicon, sapphire, silicon carbide or diamond.

As shown in FIG. 5b, Step S21: providing a sacrificial layer on the first substrate, and growing a piezoelectric material layer on the sacrificial layer.

A piezoelectric material layer 3 is a single-layer structure of one of AlN, AlGaN, and AlScN, or a multi-layer structure of any combination of AlN, AlGaN, and AlScN, and a thickness of the piezoelectric material layer 3 is greater than 500 nm. A material of the sacrificial layer 2 includes porous silicon. The sacrificial layer 2 of porous silicon is loose in structure and easy to be peeled off.

As shown in FIG. 5c, Step S3: growing a protective layer on the piezoelectric material layer.

A material of the protective layer 4 is any one of AlGaN, AlScN, AlInN, and AlInGaN.

In the present embodiment, a lattice constant of the protective layer 4 is greater than a lattice constant of the piezoelectric material layer 3. Therefore, an arrangement of the protective layer 4 may introduce a compressive stress to the piezoelectric material layer 3 to balance a tensile stress on the piezoelectric material layer 3 due to lattice mismatch between the piezoelectric material layer 3 and the first substrate 1, so that probability of an occurrence of crack in the piezoelectric material layer 3 is reduced.

As shown in FIG. 5d, Step S4: bonding the protective layer to a second substrate.

The second substrate 5 is any one of a silicon substrate, an SOI substrate, and a silicon substrate with silicon dioxide on a surface.

As shown in FIG. 5e and FIG. 5f, Step S51: peeling off the first substrate by directly utilizing thermal stress to realize self-separation of the sacrificial layer to form a piezoelectric plate including the second substrate, the protective layer and the piezoelectric material layer from bottom to top.

In the present embodiment, the sacrificial layer 2 is self-separated through the thermal stress, most of stress may be released in a self-separation process, so that the piezoelectric material layer 3 grown on the sacrificial layer 2 achieves a stress release. And a problem of cracking due to processes of polishing, finishing, and the like in a subsequent process where the piezoelectric material layer 3 serves as a substrate may be avoided. Moreover, the first substrate 1 obtained by self-separation has good crystal quality to be reused, so that a process cost is reduced.

FIG. 6 is a schematic structural diagram of a piezoelectric plate according to still another embodiment of the present disclosure. The piezoelectric plate provided in this embodiment is approximately the same as the piezoelectric plate provided in the embodiment shown in FIG. 1 and FIG. 4, and a difference merely lies in that an acoustic wave reflection layer 6 is further provided on the second substrate 5.

In this embodiment, a protective layer 4 is bonded to the acoustic wave reflection layer 6, and a first substrate 1 is peeled off. A piezoelectric plate including a second substrate 5, the acoustic wave reflection layer 6, the protective layer 4, and a piezoelectric material layer 3 from bottom to top is formed. The acoustic wave reflection layer 6 has a function of acoustic reflection. When an acoustic wave in the piezoelectric material layer 3 is transmitted to the protective layer 4 or the acoustic wave reflection layer 6, the acoustic wave is reflected back into the piezoelectric material layer 3, so that an energy loss of the acoustic wave is reduced, and performance of a device improved. The acoustic wave reflection layer 6 is made of a single-layer porous material, such as a porous silicon acoustic wave reflection layer 61, and the device has advantages of lighter weight and better flexibility.

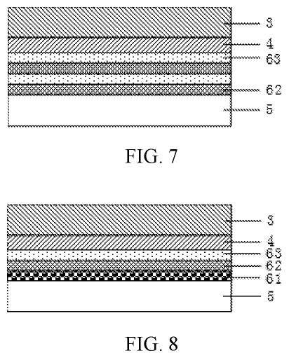

FIG. 7 is a schematic structural diagram of a piezoelectric plate according to yet still another embodiment of the present disclosure. The piezoelectric plate provided in the embodiment is approximately the same as the piezoelectric plate provided in the embodiment shown in FIG. 6, and a difference merely lies in that the acoustic wave reflection layer 6 is a multi-layer reflecting structure.

In this embodiment, the acoustic wave reflection layer 6 is an N-layer Bragg reflection structure and N is a positive integer. Each group of the Bragg reflection structure includes a low acoustic impedance layer 62 and a high acoustic impedance layer 63. When an acoustic wave reflection layer 6 at the bottom includes a plurality of groups of the Bragg reflection structures, an effect of acoustic reflection is better. The low acoustic impedance layer 62 includes a low acoustic impedance material, and may generally be any one of silicon oxide, aluminum, carbon-doped silicon oxide, nano-porous methyl silsesquioxane, nano-porous hydrogen silsesquioxane, and the like. The high acoustic impedance layer 63 includes a high acoustic resistance material, and may generally be any one of tungsten, molybdenum, platinum, ruthenium, iridium, tungsten titanium, tantalum pentoxide, hafnium oxide, aluminum oxide, silicide complex, niobium carbide, tantalum nitride, titanium carbide, titanium oxide, vanadium carbide, tungsten nitride, tungsten oxide, zirconium carbide, diamond-like or silicon-doped diamond, and the like.

FIG. 8 is a schematic structural diagram of a piezoelectric plate according to yet still another embodiment of the present disclosure. The piezoelectric plate provided in the embodiment is approximately the same as the piezoelectric plate provided in the embodiment shown in FIG. 6 and FIG. 7, and a difference merely lies in that the acoustic wave reflection layer 6 includes porous silicon and Bragg reflection structure stacked in layers.

In this embodiment, when the acoustic wave reflection layer 6 is a structure including a single-layer porous silicon and a single-group Bragg reflection structure, the device is moderately light, thin and flexible, and an acoustic wave reflection effect is moderate.

The present disclosure provides a piezoelectric plate and a manufacturing method therefor, an SAW device and a manufacturing method therefor. The manufacturing method for the piezoelectric plate provided in the present disclosure includes: sequentially growing a piezoelectric material layer and a protective layer on a first substrate, bonding the protective layer to a second substrate, and then peeling off the first substrate to form a piezoelectric plate including the second substrate, the protective layer and the piezoelectric material layer from bottom to top, where a lattice constant of the protective layer is greater than a lattice constant of the piezoelectric material layer.

Probability of occurrence of a crack in the piezoelectric material layer may be reduced by the arrangement of the protective layer in the present disclosure. And a method of transfer of the substrate may further release stress, generated by lattice mismatch and thermal mismatch between the piezoelectric material layer and the first substrate, of the piezoelectric material layer, so that an occurrence of a crack of the piezoelectric material layer may be avoided.

The acoustic wave reflection layer further prepared on the second substrate has a function of acoustic wave reflection. When an acoustic wave in the piezoelectric material layer is transmitted to the protective layer or the acoustic wave reflection layer, the acoustic wave is reflected back into the piezoelectric material layer, so that an energy loss of an acoustic wave is reduced. When the acoustic reflection layer only contains a single-layer porous material, a device has advantages of lighter weight and better flexibility. When the acoustic wave reflection layer contains a multi-layer reflecting structure, an acoustic wave reflection effect is better.

It should be understood that the term “including” and its variations used in the present disclosure are open-ended, that is, “including but not limited to”. The term “one embodiment” means “at least one embodiment”, the term “another embodiment” means “at least one other embodiment”. In this specification, the schematic expressions of the above terms do not necessarily refer to the same embodiments or examples. Moreover, the specific features, structures, materials, or characteristics described may be combined in an appropriate manner in any one or more embodiments or examples. In addition, those skilled in the art may combine and assembly different embodiments or examples described in this specification, as well as features of the different embodiments or examples, without contradiction.

The embodiments described above are only preferred embodiments of the present disclosure, and not intended to limit the protection scope of the present disclosure. Any modification, equivalent replacement, and so on that are made in the spirit and principle of the present disclosure shall fall into the protection scope of the present disclosure.

What is claimed is:

1. A manufacturing method for a piezoelectric plate, comprising:
providing a first substrate;
growing a piezoelectric material layer on the first substrate;
growing a protective layer on the piezoelectric material layer;
bonding the protective layer to a second substrate; and
peeling off the first substrate to form a piezoelectric plate comprising the second substrate, the protective layer and the piezoelectric material layer from bottom to top, wherein
a lattice constant of the protective layer is greater than a lattice constant of the piezoelectric material layer.

2. The manufacturing method for a piezoelectric plate according to claim 1, wherein the growing a piezoelectric material layer on the first substrate comprises:
providing a sacrificial layer on the first substrate; and
growing the piezoelectric material layer on the sacrificial layer.

3. The manufacturing method for a piezoelectric plate according to claim 2, wherein a material of the sacrificial layer comprises porous silicon.

4. The manufacturing method for a piezoelectric plate according to claim 2, wherein the peeling off the first substrate to form a piezoelectric plate comprising the second substrate, the protective layer and the piezoelectric material layer from bottom to top comprises:
peeling off the first substrate by directly utilizing thermal stress to realize self-separation of the sacrificial layer.

5. The manufacturing method for a piezoelectric plate according to claim 1, wherein the bonding the protective layer to a second substrate comprises:
preparing an acoustic wave reflection layer on the second substrate; and
bonding the protective layer to the acoustic wave reflection layer.

6. The manufacturing method for a piezoelectric plate according to claim 5, wherein a material of the acoustic wave reflection layer is any one of a single-layer porous material, a multi-layer reflecting structure, and a stacked structure of the single-layer porous material and the multi-layer reflecting structure.

7. The manufacturing method for a piezoelectric plate according to claim 1, wherein a material of the first substrate is one of silicon, sapphire, silicon carbide, and diamond.

8. The manufacturing method for a piezoelectric plate according to claim 1, wherein the piezoelectric material layer is a single-layer structure of one of AlN, AlGaN, and AlScN, or a multi-layer structure of any combination of AlN, AlGaN, and AlScN.

9. The manufacturing method for a piezoelectric plate according to claim 1, wherein a surface, away from the second substrate, of the piezoelectric material layer is an N surface.

10. The manufacturing method for a piezoelectric plate according to claim 1, wherein a material of the protective layer is any one of AlGaN, AlScN, AlInN, and AlInGaN.

11. A manufacturing method for a surface acoustic wave (SAW) device, comprising:
providing a piezoelectric plate according to claim 1; and
forming an interdigital transducer on the piezoelectric material layer of the piezoelectric plate.

12. A piezoelectric plate, comprising:
a second substrate;
a protective layer, disposed on the second substrate; and
a piezoelectric material layer, disposed on the protective layer, wherein
a lattice constant of the protective layer is greater than a lattice constant of the piezoelectric material layer.

13. The piezoelectric plate according to claim 12, wherein the piezoelectric material layer is a single-layer structure of one of AlN, AlGaN, and AlScN, or a multi-layer structure of any combination of AlN, AlGaN, and AlScN.

14. The piezoelectric plate according to claim 13, wherein a surface, away from the second substrate, of the piezoelectric material layer is an N surface.

15. The piezoelectric plate according to claim 12, wherein a thickness of the piezoelectric material layer is greater than 500 nm.

16. The piezoelectric plate according to claim 12, wherein a material of the protective layer is any one of AlGaN, AlScN, AlInN, and AlInGaN.

17. The piezoelectric plate according to claim 12, wherein the second substrate is one of a silicon substrate, an SOI substrate, or a silicon substrate with silicon dioxide on a surface.

18. The piezoelectric plate according to claim 12, wherein the piezoelectric plate further comprises:
an acoustic wave reflection layer, disposed between the second substrate and the protective layer.

19. The piezoelectric plate according to claim 18, wherein the acoustic wave reflection layer is a single-layer porous material or a multi-layer reflecting structure.

20. A surface acoustic wave device, comprising:
the piezoelectric plate according to claim 12 and an interdigital transducer, wherein the interdigital transducer is disposed on the piezoelectric material layer of the piezoelectric plate.
